(19) United States
(12) Patent Application Publication
(10) Pub. No.: US 2025/0221270 A1
(43) Pub. Date: Jul. 3, 2025

(54) DISPLAY APPARATUS

(71) Applicant: Samsung Display Co., LTD., Yongin-si (KR)

(72) Inventors: Jinho HYUN, Yongin-si (KR); Seungwook KWON, Yongin-si (KR); Sangtae AHN, Yongin-si (KR); Heechang YOON, Yongin-si (KR); Sangyeon HWANG, Yongin-si (KR)

(21) Appl. No.: 19/004,095

(22) Filed: Dec. 27, 2024

(30) Foreign Application Priority Data
Dec. 27, 2023 (KR) 10-2023-0193390

(51) Int. Cl. H10K 59/80

(52) U.S. Cl. CPC H10K 59/873

(57) ABSTRACT

A display apparatus includes a substrate including a display area and a peripheral area surrounding at least a portion of the display area, a first inorganic insulating layer arranged in the peripheral area, a second inorganic insulating layer disposed on the first inorganic insulating layer, an inorganic encapsulation layer disposed on the second inorganic insulating layer, and a touch insulating layer disposed on the inorganic encapsulation layer and including a first opening exposing at least a portion of the inorganic encapsulation layer, wherein a length of the first opening directed in a first direction is about 80 μm to about 500 μm.

This application claims priority to Korean Patent Application No. 10-2023-0193390, filed on Dec. 27, 2023, and all the benefits accruing therefrom under 35 U.S.C. § 119, the content of which in its entirety is herein incorporated by reference.

### BACKGROUND

### 1. Field

The invention relates to a display apparatus, and more particularly to a display apparatus having an improved quality and reliability.

### 2. Description of the Related Art

Display apparatuses visually display data. Display apparatuses may display images using light-emitting diodes. The purpose of use of display apparatuses has been diversified, and various attempts have been made to design display apparatuses with improved quality and reliability during a manufacturing process thereof.

### SUMMARY

One or more embodiments include a display apparatus.

Additional aspects will be set forth in part in the description which follows and, in part, will be apparent from the description, or may be learned by practice of the embodiments of the invention.

According to one or more embodiments, a display apparatus includes a substrate including a display area and a peripheral area surrounding at least a portion of the display area, a first inorganic insulating layer arranged in the peripheral area, a second inorganic insulating layer disposed on the first inorganic insulating layer, an inorganic encapsulation layer disposed on the second inorganic insulating layer, and a touch insulating layer disposed on the inorganic encapsulation layer and including a first opening exposing at least a portion of the inorganic encapsulation layer, wherein a length in a first direction of the first opening is about 80 μm to about 500 μm.

In an embodiment, the display apparatus may further include a first dam arranged in the peripheral area.

In an embodiment, the display apparatus may further include a crack dam arranged in the peripheral area.

In an embodiment, the first dam may be arranged to be more adjacent to the display area than the crack dam.

In an embodiment, the first opening of the touch insulating layer may be arranged between the crack dam and the first dam.

In an embodiment, the display apparatus may further include a planarization film disposed on at least a portion of the touch insulating layer.

In an embodiment, the display apparatus may further include a protective film disposed on the planarization film.

In an embodiment, the touch insulating layer may further include a second opening exposing at least a portion of the inorganic encapsulation layer and arranged to be disposed further away from the display area than the first opening.

In an embodiment, a length in the first direction of the second opening may be about 80 μm to about 500 μm.

According to one or more embodiments, a display apparatus includes a substrate including a display area and a peripheral area surrounding at least a portion of the display area, an inorganic insulating layer arranged in the peripheral area, an inorganic encapsulation layer disposed on the inorganic insulating layer, a first touch insulating layer disposed on at least a portion of the inorganic encapsulation layer, and a second touch insulating layer disposed to be in contact with an upper surface of the inorganic insulating layer, to be spaced apart in a first direction from the first touch insulating layer, and arranged to be disposed further away from the display area than the first touch insulating layer, wherein a length in the first direction by which the first touch insulating layer and the second touch insulating layer are spaced apart from each other is about 80 μm to about 500 μm.

In an embodiment, the inorganic insulating layer may extend further in a direction directed from the display area to the peripheral area than to the inorganic encapsulation layer.

In an embodiment, the display apparatus may further include a planarization film disposed on the first touch insulating layer.

In an embodiment, the display apparatus may further include a protective film disposed on the planarization film.

According to one or more embodiments, a display apparatus includes a substrate including a display area and a peripheral area surrounding at least a portion of the display area, an inorganic insulating layer arranged in the peripheral area, an inorganic encapsulation layer disposed on the inorganic insulating layer, a first touch insulating layer and a second touch insulating layer disposed on at least a portion of the inorganic encapsulation layer and spaced apart from each other in a first direction, and a third touch insulating layer arranged to be in contact with an upper surface of the inorganic insulating layer and spaced apart in the first direction from the second touch insulating layer, wherein the second touch insulating layer is disposed between the first touch insulating layer and the third touch insulating layer, and a distance by which the second touch insulating layer and the third touch insulating layer are spaced apart in the first direction from each other is about 80 μm to about 500 μm.

In an embodiment, the inorganic insulating layer may extend further in a direction directed from the display area to the peripheral area than to the inorganic encapsulation layer.

In an embodiment, the display apparatus may further include a protective film disposed on the first touch insulating layer and the second touch insulating layer.

In an embodiment, the third touch insulating layer may be disposed further away from the display area than the first touch insulating layer and the second touch insulating layer.

In an embodiment, a length by which the first touch insulating layer and the second touch insulating layer are spaced apart in the first direction from each other may be about 80 μm to about 500 μm.

In an embodiment, the display apparatus may further include a first dam arranged in the peripheral area.

In an embodiment, the display apparatus may further include a crack dam arranged in the peripheral area and arranged to be disposed further away from the display area than the first dam.

### BRIEF DESCRIPTION OF THE DRAWINGS

The above and other aspects, features, and advantages of the embodiments will be more apparent from the following description taken in conjunction with the accompanying drawings, in which:

FIG. 1 is a schematic plan view of a display apparatus, according to an embodiment;

FIG. 2 is a schematic equivalent circuit diagram of one of the sub-pixel circuits provided to a display apparatus, according to an embodiment;

FIG. 3 is a schematic cross-sectional view of a peripheral area of a display panel, according to an embodiment;

FIG. 4 is a schematic cross-sectional view of a peripheral area of a display panel, according to an embodiment;

FIG. 5 is a schematic cross-sectional view of a peripheral area of a display panel, according to an embodiment;

FIG. 6 is a schematic cross-sectional view of a peripheral area of a display panel, according to an embodiment;

FIG. 7 is a schematic cross-sectional view of a peripheral area of a display panel, according to an embodiment; and

FIG. 8 is a schematic cross-sectional view of a peripheral area of a display panel, according to an embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the invention allows for various changes and numerous embodiments, certain embodiments will be illustrated in the drawings and described in the written description. Effects and features of the invention, and methods for achieving them will be clarified with reference to embodiments described below in detail with reference to the drawings. However, the invention is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the invention is not necessarily limited thereto.

In the case where a certain embodiment may be implemented differently, a specific process order may be performed in the order different from the described order. As an example, two processes successively described may be simultaneously performed substantially and performed in the opposite order.

In the present specification, “A and/or B” means A or B, or A and B. In the present specification, “at least one of A and B” means A or B, or A and B.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system and may be interpreted in a broader sense. For example, the x-axis, the y-axis, and the z-axis may be directed perpendicular to one another, or may represent different orientations that are not perpendicular to one another.

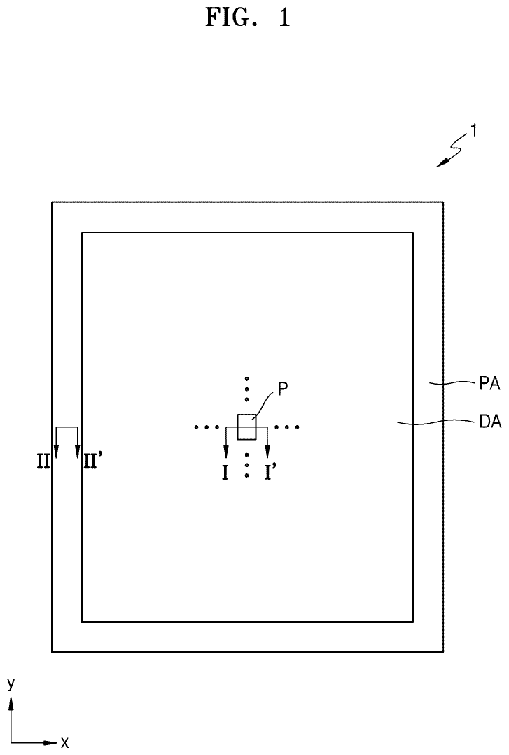

FIG. 1 is a schematic plan view of a display apparatus 1, according to an embodiment.

In an embodiment and referring to FIG. 1, the display apparatus 1 may include a display area DA and a peripheral area PA outside the display area DA. The display area DA may be configured to display images through sub-pixels P arranged in the display area DA. The peripheral area PA is arranged outside the display area DA and a non-display area in which images are not displayed. The peripheral area PA may surround the display area DA entirely. A driver and the like configured to provide electric signals or power to the display area DA may be arranged in the peripheral area PA. A pad may be arranged in the peripheral area PA, wherein the pad is a region to which electronic elements or a printed circuit board may be electrically connected.

In an embodiment, although it is shown in FIG. 1 that the display area DA is a polygon (e.g., a quadrangle) in which a length thereof in an x direction is less than a length thereof in a y direction, the invention is not limited thereto. In another embodiment, the display area DA may be a polygon (e.g., a quadrangle) in which a length thereof in the y direction is less than a length thereof in the x direction. Although FIG. 1 shows the display area DA is an approximate quadrangle, the invention is not limited thereto. In another embodiment, the display area DA may have various shapes such as an N-gon (where N is a natural number of 3 or more), a circle, or an ellipse. Although it is shown in FIG. 1 that the display area DA has a shape in which a corner of the display area DA includes a vertex at which a straight line meets a straight line, the display area DA may have a polygon having round corners in another embodiment.

Hereinafter, for convenience of description, although the embodiment where the display apparatus 1 is a smartphone is described, the display apparatus 1 is not limited thereto. In other embodiments, the display apparatus 1 is applicable to various products including televisions, notebook computers, monitors, advertisement boards, Internet of things (IoT) as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In addition, the display apparatus 1, according to an embodiment, is applicable to wearable devices including smartwatches, watchphones, glasses-type displays, and head-mounted displays (HMDs). In addition, in an embodiment, the display apparatus 1 is applicable to a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

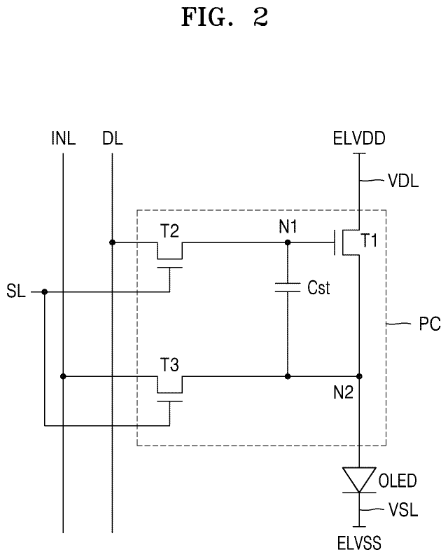

FIG. 2 is a schematic equivalent circuit diagram of one of sub-pixel circuits PC provided to the display apparatus 1, according to an embodiment.

In an embodiment and referring to FIG. 2, the sub-pixel circuit PC may include a plurality of transistors and at least one capacitor. In an embodiment, the sub-pixel circuit PC may include a first thin-film transistor T1, a second thin-film transistor T2, a third thin-film transistor T3, and a storage capacitor Cst.

In an embodiment, each of the first thin-film transistor T1, the second thin-film transistor T2, and the third thin-film transistor T3 may be an oxide semiconductor thin-film transistor including a semiconductor layer that includes an oxide semiconductor, or may be a silicon semiconductor thin-film transistor including a semiconductor layer that includes polycrystalline silicon. Each thin-film transistor may include a first electrode and a second electrode. The first electrode may be one of a source electrode and a drain electrode depending on the type of the thin-film transistor, and the second electrode may be the other of the source electrode and the drain electrode. In addition, each thin-film transistor may include a gate electrode.

In an embodiment, the first thin-film transistor T1 may be a driving thin-film transistor. The first electrode of the first thin-film transistor T1 may be connected to a driving voltage line VDL configured to supply a driving power voltage ELVDD, and the second electrode of the first thin-film transistor T1 may be connected to a pixel electrode of an organic light-emitting diode OLED. A gate electrode of the first thin-film transistor T1 may be connected to a first node N1. The first thin-film transistor T1 may be configured to control the amount of current flowing from the driving power voltage ELVDD to the organic light-emitting diode OLED according to a voltage of the first node N1.

In an embodiment, the second thin-film transistor T2 may be a switching thin-film transistor. A first electrode of the second thin-film transistor T2 may be connected to a data line DL, and a second electrode of the second thin-film transistor T2 may be connected to the first node N1. A gate electrode of the second thin-film transistor T2 may be connected to a scan line SL. When a scan signal is supplied to the scan line SL, the second thin-film transistor T2 may be turned on to electrically connect the data line DL to the first node N1.

In an embodiment, the third thin-film transistor T3 may be an initialization thin-film transistor and/or a sensing thin-film transistor. A first electrode of the third thin-film transistor T3 may be connected to a second node N2, and a second electrode of the third thin-film transistor T3 may be connected to an initialization voltage line INL. A gate electrode of the third thin-film transistor T3 may be connected to the scan line SL.

In an embodiment, when a scan signal is supplied through the scan line SL, the third thin-film transistor T3 may be turned on to electrically connect the initialization voltage line INL to the second node N2. In an embodiment, the third thin-film transistor T3 may be turned on according to a signal transferred through the scan line SL to initialize the pixel electrode of the organic light-emitting diode OLED using an initialization voltage from the initialization voltage line INL.

In an embodiment, the third thin-film transistor T3 may be turned on when a scan signal is supplied through the scan line SL to sense characteristic information of the organic light-emitting diode OLED. The third thin-film transistor T3 may serve as both the initialization thin-film transistor and the sensing thin-film transistor, or serve as one of the initialization thin-film transistor and the sensing thin-film transistor. An initialization operation and a sensing operation of the third thin-film transistor T3 may be performed respectively, or performed simultaneously. In the case where the third thin-film transistor T3 serves as the sensing thin-film transistor, the initialization voltage line INL may be called a sensing line.

In an embodiment, the storage capacitor Cst may be connected between the first node N1 and the second node N2. As an example, a first capacitor plate of the storage capacitor Cst may be connected to the gate electrode of the first thin-film transistor T1, and a second capacitor plate of the storage capacitor Cst may be connected to the pixel electrode of the organic light-emitting diode OLED.

In an embodiment, an opposite electrode of the organic light-emitting diode OLED may be connected to a common voltage line VSL providing a common power voltage ELVSS.

Although an embodiment is described in FIG. 2 that the sub-pixel circuit PC includes three thin-film transistors and one storage capacitor, the invention is not limited thereto. In another embodiment, the number of thin-film transistors and the number of storage capacitors may be variously changed according to the design of the sub-pixel circuit PC.

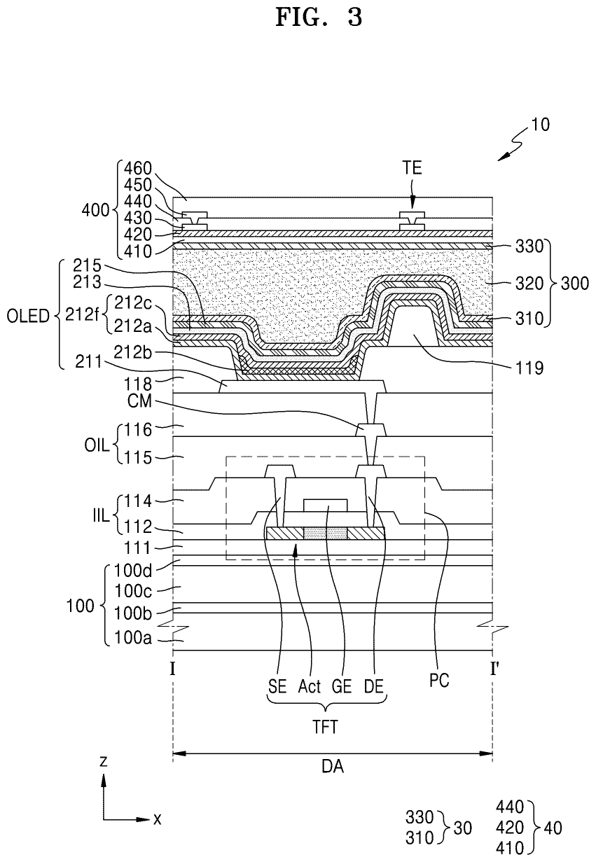

FIG. 3 is a schematic cross-sectional view of the peripheral area PA of the display apparatus 1, according to an embodiment. Specifically, FIG. 3 is a schematic cross-sectional view of the display apparatus 1 of FIG. 1, taken along line I-I′ of FIG. 1.

In an embodiment and referring to FIG. 3, a display panel 10 may include a substrate 100, an inorganic insulating layer IIL, an organic insulating layer OIL, the sub-pixel circuit PC, a connection electrode CM, the organic light-emitting diode OLED, a third organic insulating layer 118, a spacer 119, and an encapsulation layer 300. That is, the substrate 100, the inorganic insulating layer IIL, the organic insulating layer OIL, the sub-pixel circuit PC, the connection electrode CM, the organic light-emitting diode OLED, the third organic insulating layer 118, the spacer 119, and the encapsulation layer 300 may be arranged in the display area DA of the display panel 10.

In an embodiment, the substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked in the thickness direction of the substrate 100.

In an embodiment, at least one of the first base layer 110a and the second base layer 100c may include polymer resin including polyethersulfone, polyacrylate, polyetherimide, polyethylene naphthalate, polyethylene terephthalate, polyphenylene sulfide, polyimide, polycarbonate, cellulose tri acetate, and cellulose acetate propionate.

In an embodiment, the first barrier layer 100b and the second barrier layer 100d are barrier layers configured to prevent penetration of external foreign materials and may be a single layer or a multi-layer including inorganic materials such as silicon nitride (SiNx), silicon oxide (SiO₂), and/or silicon oxynitride (SiON).

In an embodiment, a buffer layer 111 may be disposed on the substrate 100. The buffer layer 111 may include an inorganic insulating material, such as silicon nitride (SiNₓ), silicon oxynitride (SiON), and silicon oxide (SiO₂), and include a single layer or a multi-layer including the inorganic insulating materials.

In an embodiment, the inorganic insulating layer IIL may be disposed on the buffer layer 111. The inorganic insulating layer IIL may include a first inorganic insulating layer 112 and a second inorganic insulating layer 114. However, the embodiment is not limited thereto.

In an embodiment, the sub-pixel circuit PC may be arranged in the display area DA. The sub-pixel circuit PC may include a thin-film transistor TFT. The thin-film transistor TFT may include a semiconductor layer Act, a gate electrode GE, a source electrode SE, and a drain electrode DE.

In an embodiment, the semiconductor layer Act may be disposed on the buffer layer 111. The semiconductor layer Act may include polycrystalline silicon. Alternatively, the semiconductor layer Act may include amorphous silicon, an oxide semiconductor, or an organic semiconductor. The semiconductor layer Act may include a channel region, a drain region, and a source region, the drain region and the source region being on two opposite sides of the channel region.

In an embodiment, the gate electrode GE may be disposed over the semiconductor layer Act. The gate electrode GE may overlap the channel region. The gate electrode GE may include a low-resistance metal material. The gate electrode GE may include a conductive material including molybdenum (Mo), aluminum (Al), copper (Cu), and titanium (Ti) and have a single-layered structure or a multi-layered structure including the above materials.

In an embodiment, the first inorganic insulating layer 112 may be disposed between the semiconductor layer Act and the gate electrode GE. The first inorganic insulating layer 112 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

In an embodiment, the second inorganic insulating layer 114 may be disposed on the gate electrode GE. The second inorganic insulating layer 114 may cover the gate electrode GE. The second inorganic insulating layer 114 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

In an embodiment, the drain electrode DE and the source electrode SE may each be disposed on the second inorganic insulating layer 114. The drain electrode DE and the source electrode SE may each be connected to the semiconductor layer Act through a contact hole provided in the first inorganic insulating layer 112 and the second inorganic insulating layer 114. The drain electrode DE and the source electrode SE may each include a material having high conductivity. The drain electrode DE and the source electrode SE may each include a conductive material including molybdenum (Mo), aluminum (Al), copper (Cu), and titanium (Ti) and include a single layer or a multi-layer including the above materials. As an example, the drain electrode DE and the source electrode SE may each have a multi-layered structure of Ti/Al/Ti.

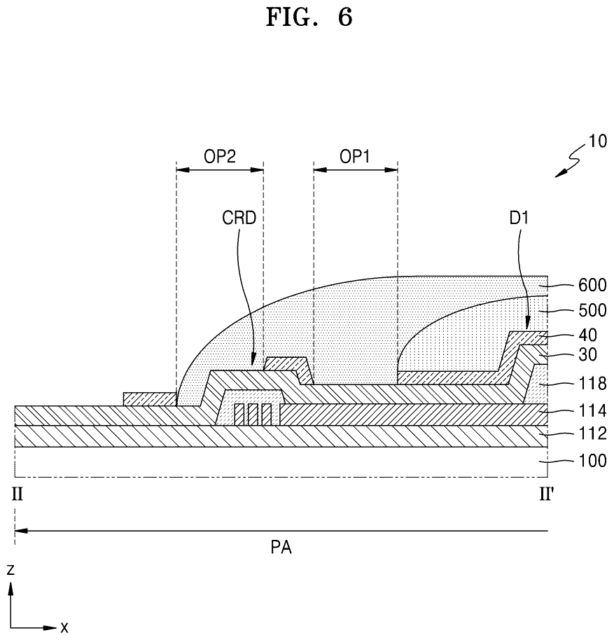

In an embodiment, the organic insulating layer OIL may be disposed on the inorganic insulating layer IIL. The organic insulating layer OIL may include a first organic insulating layer 115 and a second organic insulating layer 116. Although it is shown in FIG. 6 that two organic insulating layers OIL are provided, the invention is not limited thereto. In another embodiment, there may be three or four organic insulating layers OIL.

In an embodiment, the first organic insulating layer 115 may cover the drain electrode DE and the source electrode SE. The first organic insulating layer 115 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

In an embodiment, the connection electrode CM may be disposed on the first organic insulating layer 115. In this case, the connection electrode CM may be connected to the drain electrode DE or the source electrode SE through a contact hole of the first organic insulating layer 115. The connection electrode CM may include a material having high conductivity. The connection electrode CM may include a conductive material including molybdenum (Mo), aluminum (Al), copper (Cu), and titanium (Ti) and have a single-layered structure or a multi-layered structure including the above materials. As an example, the connection electrode CM may have a multi-layered structure of Ti/Al/Ti.

In an embodiment, the second organic insulating layer 116 may be disposed on the connection electrode CM. The second organic insulating layer 116 may cover the connection electrode CM. The second organic insulating layer 116 may include a material that is the same as or different from a material of the first organic insulating layer 115.

In an embodiment, a light-emitting diode may be disposed on the second organic insulating layer 116. As an example, the organic light-emitting diode OLED may be disposed on the second organic insulating layer 116. In another embodiment, although not shown, an inorganic light-emitting diode and the like may be disposed on the second organic insulating layer 116.

In an embodiment, the organic light-emitting diode OLED may be configured to emit red, green, or blue light, or emit red, green, blue, or white light. The organic light-emitting diode OLED may include a first electrode 211, an emission layer 212b, a functional layer 212f, a second electrode 213, and a capping layer 215. The first electrode 211 may be a pixel electrode (e.g., an anode) of the organic light-emitting diode OLED, and the second electrode 213 may be an opposite electrode (e.g., a cathode) of the organic light-emitting diode OLED.

In an embodiment, the first electrode 211 may be disposed on the second organic insulating layer 116. The first electrode 211 may be electrically connected to the connection electrode CM through a contact hole defined in the second organic insulating layer 116. The first electrode 211 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment, the first electrode 211 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In an embodiment, the first electrode 211 may further include a layer on/under the reflective layer, the layer including ITO, IZO, ZnO, or In₂O₃. As an example, the first electrode 211 may have a multi-layered structure of ITO/Ag/ITO.

In an embodiment, the third organic insulating layer 118 may be disposed on the first electrode 211, wherein an opening exposing at least a portion of the first electrode 211 is defined in the third organic insulating layer 118. An emission area of light emitted from the organic light-emitting diode OLED may be defined by the opening defined in the third organic insulating layer 118. As an example, the width of the opening may correspond to the width of the emission area.

In an embodiment, the third organic insulating layer 118 may include an organic insulating material. In another embodiment, the third organic insulating layer 118 may include an inorganic insulating material such as silicon nitride, silicon oxynitride, or silicon oxide. In another embodiment, the third organic insulating layer 118 may include an organic insulating material and an inorganic insulating material. In an embodiment, the third organic insulating layer 118 may include a light-blocking material. The light-blocking material may include carbon black, carbon nanotubes, resin or paste including black dye, metal particles, for example, nickel, aluminum, molybdenum, and an alloy thereof, metal oxide particles (e.g., chrome oxide) or metal nitride particles (e.g., chrome nitride). In the embodiment where the third organic insulating layer 118 includes a light-blocking material, external light reflection by metal structures disposed below the third organic insulating layer 118 may be reduced.

In an embodiment, the spacer 119 may be disposed on the third organic insulating layer 118. The spacer 119 may include an organic insulating material such as polyimide. In another embodiment, the spacer 119 may include an inorganic insulating material, such as silicon nitride (SiNₓ) or silicon oxide (SiO₂), or include an organic insulating material and an inorganic insulating material.

In an embodiment, the spacer 119 may include the same material as a material of the third organic insulating layer 118. In this embodiment, the third organic insulating layer 118 and the spacer 119 may be simultaneously formed during a mask process that uses a half-tone mask. In another embodiment, the spacer 119 may include a different material from a material of the third organic insulating layer 118.

In an embodiment, the emission layer 212b may be disposed in the opening of the third organic insulating layer 118. The emission layer 212b may include a polymer organic material or a low-molecular weight organic material emitting light having a preset color.

In an embodiment, the functional layer 212f may include a first functional layer 212a and/or a second functional layer 212c. The first functional layer 212a may be disposed between the first electrode 211 and the emission layer 212b, and the second functional layer 212c may be disposed between the emission layer 212b and the second electrode 213. However, at least one of the first functional layer 212a and the second functional layer 212c may be omitted. Hereinafter, the case where the first functional layer 212a and the second functional layer 212c are disposed is mainly described in detail.

In an embodiment, the first functional layer 212a may include a hole transport layer (HTL) and/or a hole injection layer (HIL). The second functional layer 212c may include an electron transport layer (ETL) and/or an electron injection layer (EIL). Like the second electrode 213 described below, the first functional layer 212a and/or the second functional layer 212c may be common layers covering the substrate 100 entirely.

In an embodiment, the second electrode 213 may be disposed on the functional layer 212f. The second electrode 213 may include a conductive material having a low work function. As an example, the second electrode 213 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. In another embodiment, the second electrode 213 may further include a layer on the (semi) transparent layer, the layer including ITO, IZO, ZnO, or In₂O₃.

In an embodiment, the capping layer 215 may be disposed on the second electrode 213. The capping layer 215 may include lithium fluoride (LiF), an inorganic material, and/or an organic material.

In an embodiment, the encapsulation layer 300 may be disposed on the organic light-emitting diode OLED. The encapsulation layer 300 may cover the organic light-emitting diode OLED. The encapsulation layer 300 may be disposed on the second electrode 213 and/or the capping layer 215. In an embodiment, the encapsulation layer 300 may include at least one inorganic encapsulation layer 30 and at least one organic encapsulation layer. It is shown in FIG. 3 that the encapsulation layer 300 includes a first inorganic encapsulation layer 310, an organic encapsulation layer 320, and a second inorganic encapsulation layer 330.

In an embodiment, the inorganic encapsulation layer 30 may include the first inorganic encapsulation layer 310 and the second inorganic encapsulation layer 330. The first and second inorganic encapsulation layers 310 and 330 may include at least one inorganic material among aluminum oxide, titanium oxide, tantalum oxide, hafnium oxide, zinc oxide, silicon oxide, silicon nitride, silicon oxynitride, and the like. The first and second inorganic encapsulation layers 310 and 330 may include a single layer or a multi-layer including the above materials. The organic encapsulation layer 320 may include a polymer-based material. The polymer-based material may include acryl-based resin, epoxy-based resin, polyimide, and polyethylene. In an embodiment, the organic encapsulation layer 320 may include acrylate.

In an embodiment, the input sensing layer 400 may be disposed on the encapsulation layer 300. An input sensing layer 400 may include a first touch insulating layer 410, a second touch insulating layer 420, a first conductive layer 430, a third touch insulating layer 440, a second conductive layer 450, and a planarization layer 460. A touch insulating layer 40 may include the first touch insulating layer 410, the second touch insulating layer 420, and/or the third touch insulating layer 440.

In an embodiment, the first touch insulating layer 410 may be disposed on the second inorganic encapsulation layer 330, and the second touch insulating layer 420 may be disposed on the first touch insulating layer 410. In an embodiment, the first touch insulating layer 410 and the second touch insulating layer 420 may each include an organic insulating material.

In an embodiment, at least one of the first touch insulating layer 410 and the second touch insulating layer 420 may be omitted. As an example, the first touch insulating layer 410 may be omitted. In this embodiment, the second touch insulating layer 420 may be disposed on the second inorganic encapsulation layer 330, and the first conductive layer 430 may be disposed on the second touch insulating layer 420.

In an embodiment, the first conductive layer 430 may be disposed on the second touch insulating layer 420, and the third touch insulating layer 440 may be disposed on the first conductive layer 430. In an embodiment, the third touch insulating layer 440 may include an organic insulating material.

In an embodiment, the second conductive layer 450 may be disposed on the third touch insulating layer 440. A touch electrode TE of the input sensing layer 400 may have a structure in which the first conductive layer 430 is connected to the second conductive layer 450. In another embodiment, the touch electrode TE may be formed on one of the first conductive layer 430 and the second conductive layer 450 and may include a metal line provided to a relevant conductive layer. Each of the first conductive layer 430 and the second conductive layer 450 may include at least one of aluminum (Al), copper (Cu), titanium (Ti), molybdenum (Mo), and indium tin oxide (ITO) and include a single layer or a multi-layer including the above materials. As an example, each of the first conductive layer 430 and the second conductive layer 450 may have a triple-layered structure of titanium layer/aluminum layer/titanium layer.

In an embodiment, the planarization layer 460 may cover the second conductive layer 450. The planarization layer 460 may include an organic insulating layer.

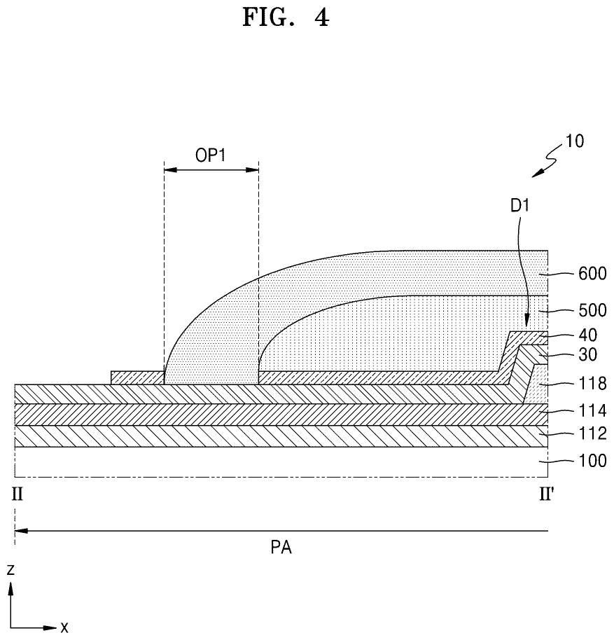

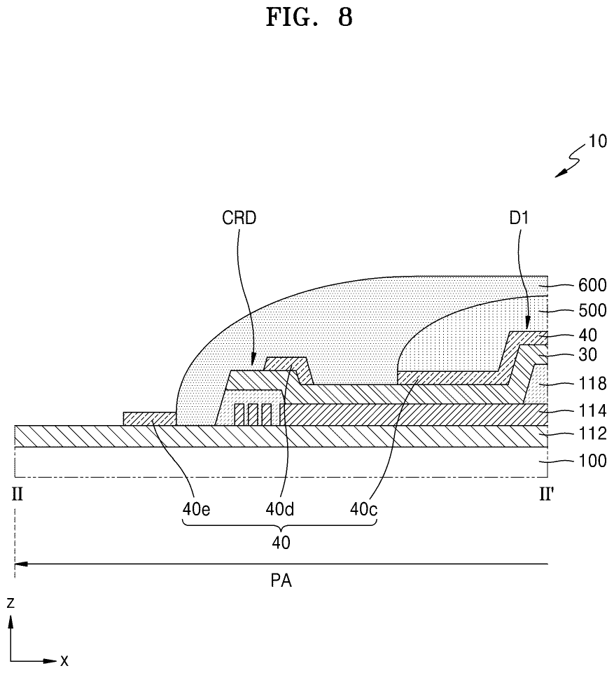

FIGS. 4 and 8 are schematic cross-sectional views of the peripheral area PA of the display panel 10, according to embodiments. Specifically, FIGS. 4 to 8 are schematic cross-sectional views of the display panel 10 of FIG. 1, taken along line II-II40 of FIG. 4.

In an embodiment and referring to FIG. 4, the substrate 100, the first inorganic insulating layer 112, the second inorganic insulating layer 114, the third organic insulating layer 118, the inorganic encapsulation layer 30, and the touch insulating layer 40 may be arranged in the peripheral area PA of the display panel 10. The substrate 100, the first inorganic insulating layer 112, the second inorganic insulating layer 114, the third organic insulating layer 118, the inorganic encapsulation layer 30, and the touch insulating layer 40 arranged in the peripheral area PA of the display panel 10 may extend from the display area DA (see FIG. 3) to the peripheral area PA. As shown in FIG. 3, the inorganic encapsulation layer 30 may include the first inorganic encapsulation layer 310 (see FIG. 3) and the second inorganic encapsulation layer 330 (see FIG. 3). In addition, the touch insulating layer 40 may include the first touch insulating layer 410 (see FIG. 3), the second touch insulating layer 420 (see FIG. 3), and/or the third touch insulating layer 440 (see FIG. 3). The first touch insulating layer 410, the second touch insulating layer 420, and the third touch insulating layer 440 of the touch insulating layer 40 may be sequentially stacked in a direction perpendicular to the substrate 100.

In an embodiment, a first dam D1 may be arranged in the peripheral area PA of the display panel 10. The first dam D1 may include at least a portion of the third organic insulating layer 118, at least a portion of the inorganic encapsulation layer 30, and at least a portion of the touch insulating layer 40.

In an embodiment, the touch insulating layer 40 arranged in the peripheral area PA of the display panel 10 may include a first opening OP1. At least a portion of the inorganic encapsulation layer 30 disposed under the first opening OP1 may be exposed by the first opening OP1 defined in the touch insulating layer 40.

In an embodiment, a planarization film 500 may be disposed on at least a portion of the touch insulating layer 40. Specifically, the planarization film 500 may be arranged to be disposed more adjacent to the display area DA (see FIG. 3) than the first opening OP1 of the touch insulating layer 40. The display area DA may be arranged in an x direction of the peripheral area PA. A protective film 600 may be disposed on the planarization film 500. Specifically, the protective film 600 may be disposed on the first opening OP1 of the touch insulating layer 40.

In an embodiment, the protective film 600 disposed on the planarization film 500 may protect the display panel 10 during a glass scribing process, which is one of the subsequent processes of ultra thin glass (UTG). The protective film 600 may be peeled off after protecting the display panel 10 during the glass scribing process. The protective film 600 may be formed by disposing a material for forming a protective film in the peripheral area PA of the display panel 10 using an inkjet process and curing the material for forming a protective film using ultraviolet (UV) ray. In this embodiment, in the case where the touch insulating layer 40 including an organic insulating material is disposed under the material for forming a protective film, the material for forming a protective film and the touch insulating layer 40 thereunder may be chemically bonded to each other during a process of forming the protective film 600 by curing the material for forming a protective film using the UV ray. Accordingly, the protective film 600 may not be peeled off after the glass scribing process.

In an embodiment, the inorganic encapsulation layer 30 instead of the touch insulating layer 40 including the organic insulating material may be arranged to be in contact with the lower surface of the protective film 600 in the edge portion of the protective film 600 arranged in the peripheral area PA of the display panel 10. Specifically, the edge portion of the protective film 600 may be arranged to be in contact with the upper surface of the inorganic encapsulation layer 30 exposed by the first opening OP1 of the touch insulating layer 40. In the embodiment where the inorganic encapsulation layer 30 is arranged to be in contact with the lower surface of the edge portion of the protective film 600, during the process of arranging the material for forming a protective film in the peripheral area PA of the display panel 10 and then forming the protective film 600 by curing the material for forming a protective film using a UV ray, the material for forming a protective film and the inorganic encapsulation layer 30 disposed thereunder may not be chemically bonded to each other. Then, the protective film 600 may be efficiently peeled off after the glass scribing process.

In an embodiment, a length in the first direction (e.g., the x direction or the −x direction) of the first opening OP1 of the touch insulating layer 40 may be about 80 μm to about 500 μm. In the case where a length in the first direction (e.g., the x direction or the −x direction) of the first opening OP1 of the touch insulating layer 40 is less than about 80 μm, the area of a portion of the protective film 600 that is in contact with the inorganic encapsulation layer 30 exposed by the first opening OP1 of the touch insulating layer 40 may not be sufficient to secure peeling force of the protective film 600 after the glass scribing process. In the embodiment where a length in the first direction (e.g., the x direction or the −x direction) of the first opening OP1 of the touch insulating layer 40 exceeds about 500 μm, the area of the peripheral area PA of the display panel 10 increases and an area in which images are not displayed increases. Accordingly, the quality and reliability of the display apparatus 1 may deteriorate.

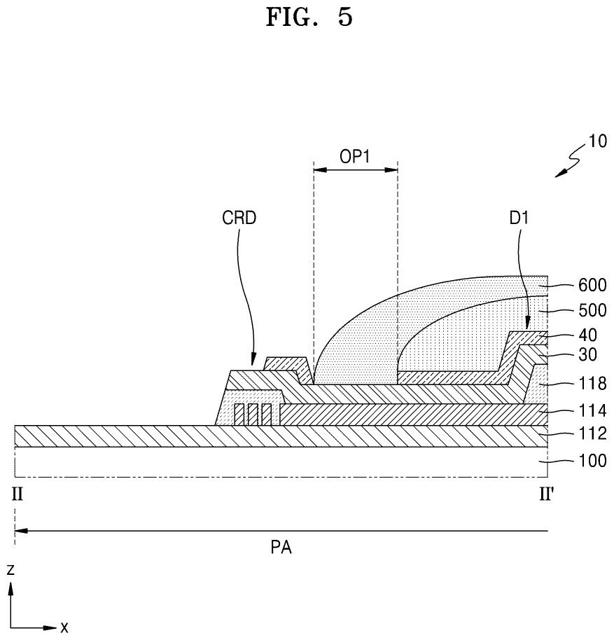

In an embodiment and referring to FIG. 5, not only the first dam D1 but also a crack dam CRD may be also arranged in the peripheral area PA of the display panel 10. The display area DA (see FIG. 3) of the display panel 10 may be arranged in the x direction of the peripheral area PA. The first dam D1 may be arranged to be disposed more adjacent to the display area DA of the display panel 10 than the crack dam CRD. In other words, the crack dam CRD may be arranged to be disposed further away from the display area DA of the display panel 10 than the first dam D1.

In an embodiment, the crack dam CRD may include at least a portion of the second inorganic insulating layer 114, at least a portion of the third organic insulating layer 118, and at least a portion of the inorganic encapsulation layer 30. The second inorganic insulating layer 114 of the crack dam CRD may be provided in a shape of a plurality of pillars, and the third organic insulating layer 118 may be arranged to cover the second inorganic insulating layer 114 in the shape of a plurality of pillars.

In an embodiment, the touch insulating layer 40 may be disposed on the inorganic encapsulation layer 30 to be arranged in the peripheral area PA of the display panel 10. The touch insulating layer 40 may include the first opening OP1. The first opening OP1 of the touch insulating layer 40 may be arranged between the crack dam CRD and the first dam D1. At least a portion of the inorganic encapsulation layer 30 disposed under the first opening OP1 may be exposed by the first opening OP1 of the touch insulating layer 40.

In an embodiment, the planarization film 500 may be disposed on at least a portion of the touch insulating layer 40. Specifically, the planarization film 500 may be arranged to be disposed more adjacent to the display area DA (see FIG. 3) than the first opening OP1 of the touch insulating layer 40. The display area DA may be arranged in the x direction of the peripheral area PA. The protective film 600 may be disposed on the planarization film 500. Specifically, the protective film 600 may be disposed on the first opening OP1 of the touch insulating layer 40.

In an embodiment, the protective film 600 may be disposed in the first opening OP1 of the touch insulating layer 40, and at least a portion of the lower surface of the edge portion of the protective film 600 may be in contact with the upper surface of the inorganic encapsulation layer 30 exposed by the first opening OP1 of the touch insulating layer 40. Because at least a portion of the lower surface of the protective film 600 is formed to be in contact with the inorganic encapsulation layer 30, during the process of arranging the material for forming a protective film using an inkjet process and then forming the protective film 600 by curing the material for forming a protective film using a UV ray, the material for forming a protective film and the inorganic encapsulation layer 30 disposed thereunder to be in contact with the lower surface thereof may not be chemically bonded to each other. Then, the protective film 600 may be efficiently peeled off after the glass scribing process.

In an embodiment, a length in the first direction (e.g., the x direction or the −x direction) of the touch insulating layer 40 may be about 80 μm to about 500 μm. In the embodiment where a length in the first direction (e.g., the x direction or the −x direction) of the touch insulating layer 40 is less than about 80 μm, the area of a portion of the protective film 600 that is in contact with the inorganic encapsulation layer 30 exposed by the first opening OP1 of the touch insulating layer 40 may not be sufficient to secure peeling force of the protective film 600 after the glass scribing process. In the embodiment where a length in the first direction (e.g., the x direction or the −x direction) of the touch insulating layer 40 exceeds about 500 μm, the area of the peripheral area PA of the display panel 10 increases and an area in which images are not displayed increases. Accordingly, the quality and reliability of the display apparatus 1 may deteriorate.

Referring to FIG. 6, the inorganic encapsulation layer 30 may further extend from the display area DA (see FIG. 3) to the peripheral area PA of the display panel 10, according to the embodiment shown in FIG. 5. In an embodiment, the display area DA may be arranged in an x direction of the peripheral area PA. In addition, the touch insulating layer 40 may further include not only the first opening OP1 but also a second opening OP2. The protective film 600 may be disposed on the first opening OP1 and the second opening OP2 of the touch insulating layer 40. Because elements and arrangements thereof of an embodiment shown in FIG. 6 are the same as those of the embodiment shown in FIG. 5, descriptions of the same elements and arrangements thereof are omitted below.

In an embodiment, the inorganic encapsulation layer 30 may be successively arranged in the peripheral area PA of the display panel 10. In addition, the touch insulating layer 40 may include the first opening OP1 and the second opening OP2. The first opening OP1 of the touch insulating layer 40 may be arranged between the crack dam CRD and the first dam D1. The second opening OP2 of the touch insulating layer 40 may overlap the crack dam CRD. At least a portion of the inorganic encapsulation layer 30 disposed under the first opening OP1 and the second opening OP2 may be exposed by the first opening OP1 and the second opening OP2 of the touch insulating layer 40.

In an embodiment, a planarization film 500 may be disposed on at least a portion of the touch insulating layer 40. Specifically, the planarization film 500 may be arranged to be disposed more adjacent to the display area DA than the first opening OP1 of the touch insulating layer 40. A protective film 600 may be disposed on the planarization film 500. Specifically, the protective film 600 may be disposed on the first opening OP1 and/or the second opening OP2 of the touch insulating layer 40.

In an embodiment, the protective film 600 may be disposed in the first opening OP1 and/or the second opening OP2 of the touch insulating layer 40, and at least a portion of the lower surface of the protective film 600 may be in contact with the upper surface of the inorganic encapsulation layer 30 that is exposed by the first opening OP1 and/or the second opening OP2 of the touch insulating layer 40. Because at least a portion of the lower surface of the protective film 600 is formed to be in contact with the inorganic encapsulation layer 30, during the process of arranging the material for forming a protective film using an inkjet process and then forming the protective film 600 by curing the material for forming a protective film using a UV ray, the material for forming a protective film and the inorganic encapsulation layer 30 disposed thereunder to be in contact with the lower surface thereof may not be chemically bonded to each other. Then, the protective film 600 may be efficiently peeled off after the glass scribing process.

In an embodiment, a length in the first direction (e.g., the x direction or the −x direction) of the first opening OP1 and the second opening OP2 of the touch insulating layer 40 may be about 80 μm to about 500 μm. In the embodiment where a length in the first direction (e.g., the x direction or the −x direction) of the first opening OP1 and the second opening OP2 of the touch insulating layer 40 is less than about 80 μm, the area of a portion of the protective film 600 that is in contact with the inorganic encapsulation layer 30 exposed by the first opening OP1 and the second opening OP2 of the touch insulating layer 40 may not be sufficient to secure peeling force of the protective film 600 after the glass scribing process. In the embodiment where a length in the first direction (e.g., the x direction or the −x direction) of the first opening OP1 and the second opening OP2 of the touch insulating layer 40 exceeds about 500 μm, the area of the peripheral area PA of the display panel 10 increases and an area in which images are not displayed increases. Accordingly, the quality and reliability of the display apparatus 1 may deteriorate.

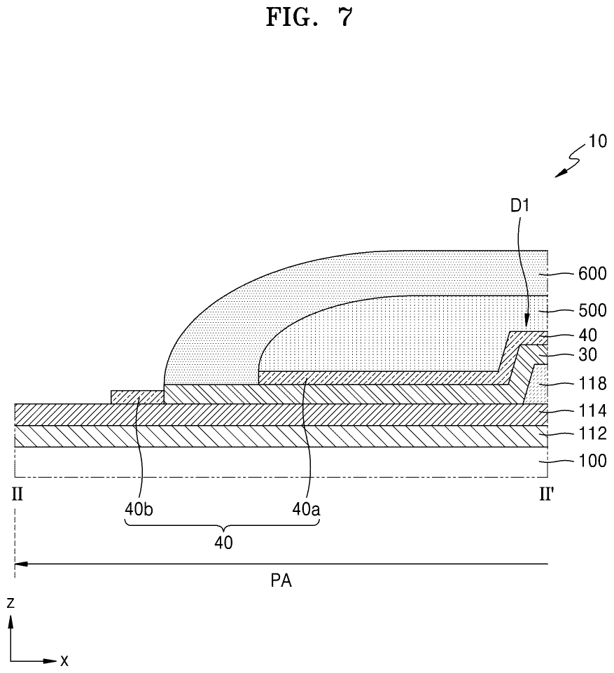

In an embodiment and referring to FIG. 7, the substrate 100, the first inorganic insulating layer 112, the second inorganic insulating layer 114, the third organic insulating layer 118, the inorganic encapsulation layer 30, and the touch insulating layer 40 may be arranged in the peripheral area PA of the display panel 10. As shown in FIG. 3, the inorganic encapsulation layer 30 may include the first inorganic encapsulation layer 310 (see FIG. 3) and the second inorganic encapsulation layer 330 (see FIG. 3). In addition, the touch insulating layer 40 may include the first touch insulating layer 410 (see FIG. 3), the second touch insulating layer 420 (see FIG. 3), and the third touch insulating layer 440 (see FIG. 3). The first touch insulating layer 410, the second touch insulating layer 420, and the third touch insulating layer 440 of the touch insulating layer 40 may be sequentially stacked in a direction perpendicular to the substrate 100.

In an embodiment, the inorganic encapsulation layer 30 disposed on the second inorganic insulating layer 114 may be patterned. As shown in FIG. 3, the display area DA may be arranged in the x direction of the peripheral area PA. Specifically, the first inorganic insulating layer 112 and/or the second inorganic insulating layer 114 may extend further in a direction from the display area DA toward the peripheral area PA than the inorganic encapsulation layer 30. In other words, a length in the first direction (e.g., the x direction or the −x direction) of the inorganic encapsulation layer 30 arranged in the peripheral area PA may be less than a length in the first direction (e.g., the x direction or the −x direction) of the first inorganic insulating layer 112 or the second inorganic insulating layer 114 arranged in the peripheral area PA.

In an embodiment, the first dam D1 may be arranged in the peripheral area PA of the display panel 10. The first dam D1 may include at least a portion of the third organic insulating layer 118, at least a portion of the inorganic encapsulation layer 30, and at least a portion of the touch insulating layer 40.

In an embodiment, the touch insulating layer 40 arranged in the peripheral area PA of the display panel 10 may include a fourth touch insulating layer 40a and a fifth touch insulating layer 40b. The fourth touch insulating layer 40a and the fifth touch insulating layer 40b may be arranged to be spaced apart from each other in the first direction (e.g., the x direction or the-x direction). The fourth touch insulating layer 40a may be arranged to be disposed more adjacent to the display area DA than the fifth touch insulating layer 40b. In other words, the fifth touch insulating layer 40b may be arranged to be further away from the display area DA than the fourth touch insulating layer 40a.

In an embodiment, the fourth touch insulating layer 40a may be disposed on at least a portion of the inorganic encapsulation layer 30. Specifically, the fourth touch insulating layer 40a may be disposed to be in contact with the upper surface of the inorganic encapsulation layer 30. The fifth touch insulating layer 40b may be disposed on the first inorganic insulating layer 112 and/or the second inorganic insulating layer 114 arranged in the-x direction of the inorganic encapsulation layer 30. Specifically, the fifth touch insulating layer 40b may be disposed to be in contact with the upper surface of the second inorganic insulating layer 114.

In an embodiment, the planarization film 500 may be disposed on at least a portion of the fourth touch insulating layer 40a. Specifically, the planarization film 500 may be arranged up to the edge portion of the fourth touch insulating layer 40a. The protective film 600 may be disposed on the planarization film 500. Specifically, the protective film 600 may be disposed on a portion by which the fourth touch insulating layer 40a is spaced apart from the fifth touch insulating layer 40b.

In an embodiment, due to the portion by which the fourth touch insulating layer 40a is spaced apart from the fifth touch insulating layer 40b, at least a portion of the inorganic encapsulation layer 30 disposed under the fourth touch insulating layer 40a may be exposed. In other words, the inorganic encapsulation layer 30 may be disposed to be in contact with the lower surface of the edge portion of the protective film 600. Because the protective film 600 is disposed to be in contact with the upper surface of the inorganic encapsulation layer 30 exposed when the fourth touch insulating layer 40a is spaced apart from the fifth touch insulating layer 40b, during the process of arranging the material for forming a protective film in the peripheral area PA of the display panel 10 and then forming the protective film 600 by curing the material for forming a protective film using a UV ray, the material for forming a protective film and the inorganic encapsulation layer 30 disposed thereunder may not be chemically bonded to each other. Then, the protective film 600 may be efficiently peeled off after the glass scribing process.

In an embodiment, a length by which the fourth touch insulating layer 40a and the fifth touch insulating layer 40b are spaced apart from each other in the first direction (e.g., the x direction or the −x direction) may be about 80 μm to about 500 μm. In the embodiment where a length by which the fourth touch insulating layer 40a and the fifth touch insulating layer 40b are spaced apart from each other in the first direction (e.g., the x direction or the −x direction) is less than about 80 μm, the area of a portion of the protective film 600 that is in contact with the upper surface of the inorganic encapsulation layer 30 may not be sufficient to secure peeling force of the protective film 600 after the glass scribing process. In the embodiment where a length by which the fourth touch insulating layer 40a and the fifth touch insulating layer 40b are spaced apart from each other in the first direction (e.g., the x direction or the −x direction) exceeds about 500 μm, the area of the peripheral area PA of the display panel 10 increases and an area in which images are not displayed increases. Accordingly, the quality and reliability of the display apparatus 1 may deteriorate.

In an embodiment and referring to FIG. 8, not only the first dam D1 but also a crack dam CRD may be also arranged in the peripheral area PA of the display panel 10. As shown in FIG. 3, the display area DA of the display panel 10 may be arranged in the x direction of the peripheral area PA. The first dam D1 may be arranged to be disposed more adjacent to the display area DA of the display panel 10 than the crack dam CRD. In other words, the crack dam CRD may be arranged to be disposed further away from the display area DA of the display panel 10 than the first dam D1.

In an embodiment, the crack dam CRD may include at least a portion of the second inorganic insulating layer 114, at least a portion of the third organic insulating layer 118, and at least a portion of the inorganic encapsulation layer 30. The second inorganic insulating layer 114 of the crack dam CRD may be provided in a shape of a plurality of pillars, and the third organic insulating layer 118 may be arranged to cover the second inorganic insulating layer 114 in the shape of a plurality of pillars.

In an embodiment, the touch insulating layer 40 arranged in the peripheral area PA of the display panel 10 may include a sixth touch insulating layer 40c, a seventh touch insulating layer 40d, and an eighth touch insulating layer 40e. The sixth touch insulating layer 40c may be arranged to be disposed more adjacent to the display area than the seventh touch insulating layer 40d and the eighth touch insulating layer 40e. The eighth touch insulating layer 40e may be arranged to be disposed further away from the display area DA than the sixth touch insulating layer 40c and the seventh touch insulating layer 40d. The seventh touch insulating layer 40d may be arranged between the sixth touch insulating layer 40c and the eighth touch insulating layer 40e.

In an embodiment, the sixth touch insulating layer 40c and the seventh touch insulating layer 40d may be arranged to be spaced apart from each other in the first direction (e.g., the x direction or the −x direction) on at least a portion of the inorganic encapsulation layer 30. Specifically, the sixth touch insulating layer 40c may overlap the first dam D1 and the seventh touch insulating layer 40d may overlap the crack dam CRD. The eighth touch insulating layer 40e may be arranged in the −x direction of the crack dam CRD. Because the first inorganic insulating layer 112 extends in a direction from the display area DA toward the peripheral area PA in the −x direction of the crack dam CRD, the eighth touch insulating layer 40e may be disposed to be in contact with the upper surface of the first inorganic insulating layer 112.

In an embodiment, the planarization film 500 may be disposed on the sixth touch insulating layer 40c. Specifically, the planarization film 500 may be arranged up to the edge portion of the sixth touch insulating layer 40c. A protective film 600 may be disposed on the planarization film 500. Specifically, the protective film 600 may be disposed on the sixth touch insulating layer 40c and the seventh touch insulating layer 40d. The protective film 600 may be arranged to extend to the edge of the eighth touch insulating layer 40e in the x direction.

In an embodiment, due to a portion by which the sixth touch insulating layer 40c and the seventh touch insulating layer 40d are spaced apart from each other, at least a portion of the inorganic encapsulation layer 30 disposed under the sixth touch insulating layer 40c and the seventh touch insulating layer 40d may be exposed. Due to the portion by which the seventh touch insulating layer 40d and the eighth touch insulating layer 40e are spaced apart from each other, at least a portion of the first inorganic encapsulation layer 310 disposed under the eighth touch insulating layer 40e may be exposed. In other words, the inorganic encapsulation layer 30 and the first inorganic insulating layer 112 may be disposed to be in contact with the lower surface of the edge portion of the protective film 600. Because the protective film 600 is arranged to be in contact with the upper surface of the inorganic encapsulation layer 30 and the first inorganic insulating layer 112 exposed when the sixth touch insulating layer 40c, the seventh touch insulating layer 40d, and the eighth touch insulating layer 40e are apart from each other, during the process of arranging the material for forming a protective film in the peripheral area PA of the display panel 10 and then forming the protective film 600 by curing the material for forming a protective film using a UV ray, the material for forming a protective film and the inorganic encapsulation layer 30 and the first inorganic insulating layer 112 disposed thereunder may not be chemically bonded to each other. Then, the protective film 600 may be efficiently peeled off after the glass scribing process.

In an embodiment, a length by which the sixth touch insulating layer 40c and the seventh touch insulating layer 40d are spaced apart from each other in the first direction (e.g., the x direction or the −x direction), and a length by which the seventh touch insulating layer 40d and the eighth touch insulating layer 40e are apart from each other in the first direction (e.g., the x direction or the −x direction) may be about 80 μm to about 500 μm. In the embodiment where a length by which the sixth touch insulating layer 40c and the seventh touch insulating layer 40d are spaced apart from each other in the first direction (e.g., the x direction or the −x direction), and a length by which the seventh touch insulating layer 40d and the eighth touch insulating layer 40e are spaced apart from each other in the first direction (e.g., the x direction or the −x direction) are less than about 80 μm, the area of a portion of the protective film 600 that is in contact with the upper surface of the inorganic encapsulation layer 30 may not be sufficient to secure peeling force of the protective film 600 after the glass scribing process. In the embodiment where a length by which the sixth touch insulating layer 40c and the seventh touch insulating layer 40d are spaced apart from each other in the first direction (e.g., the x direction or the −x direction), and a length by which the seventh touch insulating layer 40d and the eighth touch insulating layer 40e are spaced apart from each other in the first direction (e.g., the x direction or the −x direction) exceed about 500 μm, the area of the peripheral area PA of the display panel 10 increases and an area in which images are not displayed increases. Accordingly, the quality and reliability of the display apparatus 1 may deteriorate.

In an embodiment, the upper surface of the inorganic encapsulation layer 30 or the inorganic insulating layer 112 (or 114) exposed by the opening OP1 (or OP2) of the touch insulating layer 40 or a portion of the touch insulating layer 40 that is spaced apart in the first direction (e.g., the x direction or the −x direction), and the lower surface of the protective film 600 disposed on the upper surface may be disposed to be in contact with each other, wherein the touch insulating layer 40 is arranged in the peripheral area PA of the display panel 10. A length in the first direction (e.g., the x direction or the −x direction) of the opening OP1 (or OP2) of the touch insulating layer 40 or a portion of the touch insulating layer 40 is spaced apart may be about 80 μm to about 500 μm. Because the inorganic encapsulation layer 30 or the inorganic insulating layer 112 (or 114) exposed by the opening OP1 (or OP2) of the touch insulating layer 40 or a portion of the touch insulating layer 40 that is spaced apart, and the lower surface of the edge portion of the protective film 600 disposed thereon are disposed to be in contact with each other, during the process of arranging the material for forming a protective film in the peripheral area PA of the display panel 10 and then forming the protective film 600 by curing the material for forming a protective film using a UV ray, the material for forming a protective film and the inorganic encapsulation layer 30 and the first inorganic insulating layer 112 disposed thereunder may not be chemically bonded to each other. Then, the protective film 600 may be efficiently peeled off after the glass scribing process.

According to an embodiment having the above configuration, the display apparatus with improved quality and reliability may be implemented. However, the scope of the invention is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims. Moreover, the embodiments or parts of the embodiments may be combined in whole or in part without departing from the scope of the invention.

What is claimed is:

1. A display apparatus comprising:
a substrate including a display area and a peripheral area surrounding at least a portion of the display area;
a first inorganic insulating layer arranged in the peripheral area;
a second inorganic insulating layer disposed on the first inorganic insulating layer;
an inorganic encapsulation layer disposed on the second inorganic insulating layer; and
a touch insulating layer disposed on the inorganic encapsulation layer and including a first opening exposing at least a portion of the inorganic encapsulation layer,
wherein a length of the first opening directed in a first direction is about 80 μm to about 500 μm.

2. The display apparatus of claim 1, further comprising a first dam arranged in the peripheral area.

3. The display apparatus of claim 2, further comprising a crack dam arranged in the peripheral area.

4. The display apparatus of claim 3, wherein the first dam is arranged to be disposed more adjacent to the display area than the crack dam.

5. The display apparatus of claim 4, wherein the first opening of the touch insulating layer is disposed between the crack dam and the first dam.

6. The display apparatus of claim 1, further comprising a planarization film disposed on at least a portion of the touch insulating layer.

7. The display apparatus of claim 6, further comprising a protective film disposed on the planarization film.

8. The display apparatus of claim 1, wherein the touch insulating layer further includes a second opening exposing at least a portion of the inorganic encapsulation layer and arranged to be disposed further away from the display area than the first opening.

9. The display apparatus of claim 8, wherein a length of the second opening in the first direction is about 80 μm to about 500 μm.

10. A display apparatus comprising:
a substrate including a display area and a peripheral area surrounding at least a portion of the display area;
an inorganic insulating layer arranged in the peripheral area;
an inorganic encapsulation layer disposed on the inorganic insulating layer;
a first touch insulating layer disposed on at least a portion of the inorganic encapsulation layer; and
a second touch insulating layer disposed to be in contact with an upper surface of the inorganic insulating layer, spaced apart from the first touch insulating layer in a first direction, and arranged to be disposed further away from the display area than the first touch insulating layer,
wherein a length in the first direction by which the first touch insulating layer and the second touch insulating layer are spaced apart from each other is about 80 μm to about 500 μm.

11. The display apparatus of claim 10, wherein the inorganic insulating layer extends further in a direction from the display area to the peripheral area than the inorganic encapsulation layer.

12. The display apparatus of claim 10, further comprising a planarization film disposed on the first touch insulating layer.

13. The display apparatus of claim 12, further comprising a protective film disposed on the planarization film.

14. A display apparatus comprising:
a substrate including a display area and a peripheral area surrounding at least a portion of the display area;
an inorganic insulating layer arranged in the peripheral area;
an inorganic encapsulation layer disposed on the inorganic insulating layer;
a first touch insulating layer and a second touch insulating layer disposed on at least a portion of the inorganic encapsulation layer and spaced apart from each other in a first direction; and
a third touch insulating layer arranged to be in contact with an upper surface of the inorganic insulating layer and spaced apart from the second touch insulating layer in the first direction,
wherein the second touch insulating layer is disposed between the first touch insulating layer and the third touch insulating layer, and
wherein a distance by which the second touch insulating layer and the third touch insulating layer are spaced apart from each other in the first direction is about 80 μm to about 500 μm.

15. The display apparatus of claim 14, wherein the inorganic insulating layer extends further in a direction from the display area to the peripheral area than the inorganic encapsulation layer.

16. The display apparatus of claim 15, further comprising a protective film disposed on the first touch insulating layer and the second touch insulating layer.

17. The display apparatus of claim 14, wherein the third touch insulating layer is disposed further away from the display area than the first touch insulating layer and the second touch insulating layer.

18. The display apparatus of claim 14, wherein a length by which the first touch insulating layer and the second touch insulating layer are spaced apart from each other in the first direction is about 80 μm to about 500 μm.

19. The display apparatus of claim 14, further comprising a first dam arranged in the peripheral area.

20. The display apparatus of claim 19, further comprising a crack dam arranged in the peripheral area and arranged to be disposed further away from the display area than the first dam.
